(19) United States
(12) Patent Application Publication
(10) Pub. No.: US 2012/0068052 A1
(43) Pub. Date: Mar. 22, 2012

(54) OPTICAL RECEIVER CIRCUIT

(75) Inventors: Shigeyuki Sakura, Kanagawa-ken (JP); Hirofumi Kobayashi, Kanagawa-ken (JP)

(73) Assignee: KABUSHIKI KAISHA TOSHIBA, Tokyo (JP)

(21) Appl. No.: 13/238,719

(22) Filed: Sep. 21, 2011

(30) Foreign Application Priority Data
Sep. 22, 2010 (JP) 2010-212566
Sep. 13, 2011 (JP) 2011-200034

(51) Int. Cl. H03F 3/08

(52) U.S. Cl. 250/214 A

(57) ABSTRACT

An optical receiver circuit according to an embodiment includes a light receiving units configured to output a current according to input light, and an inverting amplifier having an input terminal and an output terminal, the input terminal connected to the light receiving units, and a feedback circuit connected between the input terminal and the output terminal, and provided with a plurality of pairs of a pole and a zero on a negative real axis on a Laplace plane so that transimpedance characteristics show high gains of a plurality of steps on high-frequency side.

### CROSS-REFERENCE TO RELATED APPLICATIONS

This application is based upon and claims the benefit of priority from the prior Japanese Patent Application No. 2010-212566, filed on Sep. 22, 2010, and No. 2011-200034, filed on Sep. 13, 2011; the entire contents of which are incorporated herein by reference.

### FIELD

Embodiments of the present invention relate to an optical receiver circuit.

### BACKGROUND

A conventional, generally-employed method of amplifying the minute electric current of light receiving elements, such as photo diodes (hereinafter, referred to as PDs), is current-voltage conversion using an amplifier with a small input bias current, a low input offset voltage, and a small drift. A transimpedance amplifier, where a PD is directly inserted as the input of an amplifier, is a type of the circuit used for this purpose.

A conventional optical receiver circuit includes an inverting amplifier, a light receiving element and a comparator. In the inverting amplifier, a feedback resistor is connected between an input terminal and an output terminal. The light receiving element is connected to the input terminal of the inverting amplifier. The comparator compares the output of the inverting amplifier with a threshold voltage, and outputs either a high-level voltage or a low-level voltage according to the result of the comparison.

To be more specific, if a pulse optical signal enters the light receiving element, the light receiving element supplies, to the inverting amplifier, a current corresponding to the optical signal. The inverting amplifier converts the supplied current to a voltage, and outputs a pulse voltage corresponding to the optical signal. The pulse voltage is compared by the comparator with a threshold voltage, and a pulse voltage that is equal to or higher than the threshold is detected as an optical signal.

Under some conditions of the input pulse signal inputted into the comparator, a distortion occurs in the waveform of the output pulse signal to be outputted, and such a distortion, if occurs, may possibly cause the optical receiver circuit to malfunction.

If, for instance a photo diode is used as the light receiving element, a time delay occurs due to the diffusion of the minority carriers generated outside the depletion layer of the PD, and the time delay makes the terminal end of the input pulse signal have a trailing waveform. In particular, in the case of a high-speed communication, a pulse signal with a small pulse width is more likely to be generated, and a time delay is more likely to occur. Accordingly, the waveform of the pulse signal is more likely to be trailing, and distorted pulse width occurs frequently. If a low-price light emitting diode (LED) is used as the light source of the input light, the pulse of the light source has a waveform with a slow rise or a slow fall because of the response characteristics of the LED, though depending upon the pulse width. Accordingly, the pulse signal has a trailing waveform, and a distorted pulse width occurs frequently.

In contrast, if a signal with a large pulse width is used, a phenomenon occurs in which the pulse signal rises again after the falling of the pulse signal. If the pulse signal that rises again exceeds a reference voltage Vref, the pulse signal causes the comparator to produce an erroneous output, resulting in a problem of a malfunction of the entire system.

### BRIEF DESCRIPTION OF THE DRAWINGS

FIG. 1 is a circuit diagram illustrating an optical receiver circuit according to a first embodiment.

FIG. 2 is a circuit diagram illustrating an inverting amplifier according to the first embodiment to a third embodiment.

FIG. 3 is circuit diagrams illustrating feedback circuits according to modifications of the first embodiment.

FIG. 4 is a graph showing the transimpedance characteristics of the inverting amplifier according to the first to third embodiments.

FIG. 5 is a circuit diagram according to a first comparative example.

FIG. 6 is a graph showing the transimpedance characteristics of an inverting amplifier according to the first comparative example.

FIG. 7 is timing charts showing the waveforms of pulse signals according to the first embodiment and the first comparative example.

FIG. 8 is timing charts showing the waveforms of pulse signals according to the first embodiment and the first comparative example.

FIG. 9 is a circuit diagram illustrating an optical receiver circuit according to a second embodiment.

FIG. 10 is a circuit diagram illustrating a feedback circuit according to a modification of the second embodiment.

FIG. 11 is a circuit diagram illustrating an optical receiver circuit according to the third embodiment.

FIG. 12 a circuit diagram illustrating a feedback circuit according to a modification of the third embodiment.

### DETAILED DESCRIPTION

An optical receiver circuit according to an embodiment includes: light receiving means configured to output a current according to input light; an inverting amplifier having an input terminal connected to the light receiving means; and a feedback circuit connected between an input and an output of the inverting amplifier. The feedback circuit includes a plurality of pairs of a pole and a zero on a negative real axis of a Laplace plane so that transimpedance characteristics of the inverting amplifier can have a higher gain on the higher frequency side. Specifically, the feedback circuit includes a first resistor, a second resistor, a third resistor, a fourth resistor, a first capacitor, and a second capacitor. The first resistor has a first terminal connected to an input terminal of the inverting amplifier, and a second terminal connected commonly to a first terminal of the second resistor, a first terminal of the third resistor, and a first terminal of the fourth resistor. The second resistor has a second terminal connected to an output terminal of the inverting amplifier. The third resistor has a second terminal connected to a first terminal of the first capacitor. The fourth resistor has a second terminal connected to a first terminal of the second capacitor. The first capacitor has a second terminal connected to the ground. The second capacitor has a second terminal connected to the ground.

Embodiments of the present invention are described below by referring to the drawings.

### First Embodiment

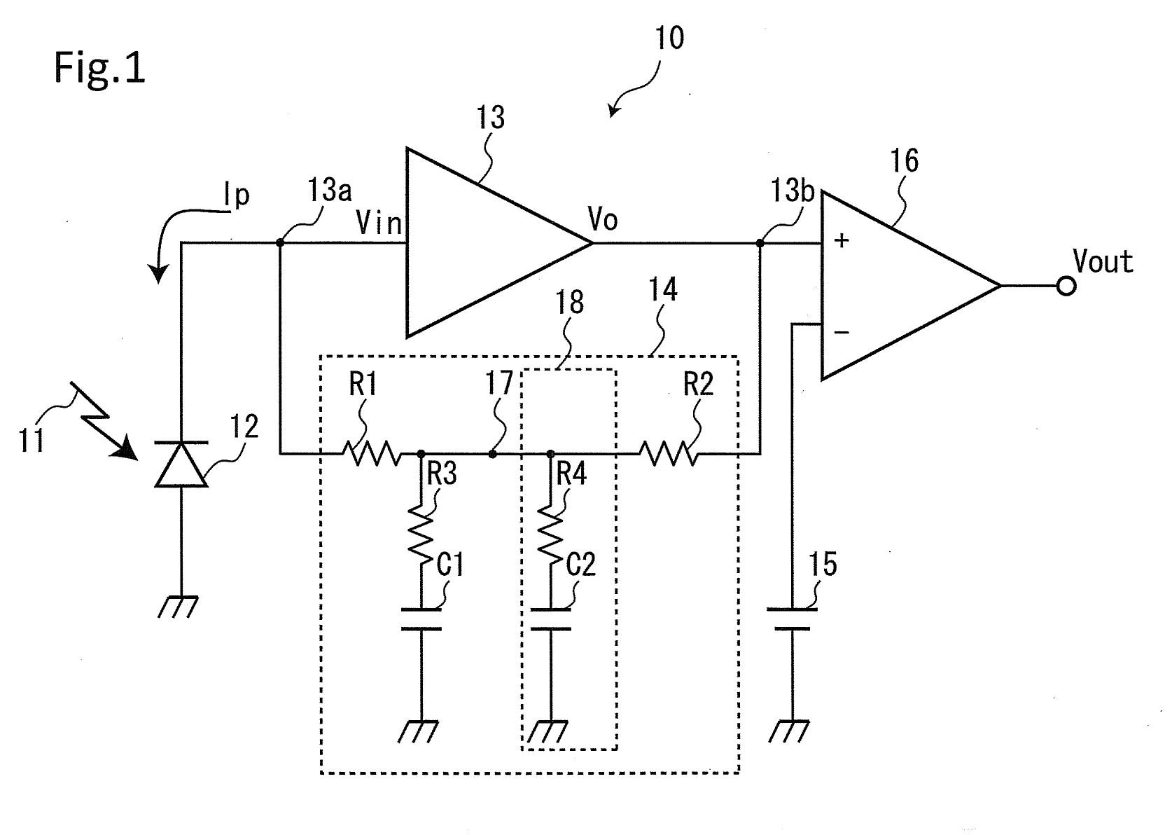

FIG. 1 is a circuit diagram illustrating an optical receiver circuit 10 according to a first embodiment. The optical receiver circuit 10 includes a light receiving element 12, an inverting amplifier 13, and a feedback circuit 14. The light receiving element 12 outputs a current Ip according to the intensity of input light 11. The inverting amplifier 13 has an input terminal 13a to which the light receiving element 12 is connected. The feedback circuit 14 has frequency characteristics with a smaller transimpedance on the low-frequency side and a higher transimpedance on the high-frequency side. The feedback circuit 14 feeds an output voltage Vo of the inverting amplifier 13 back to the input side.

The optical receiver circuit 10 further includes a comparator 16 that has a non-inverting input terminal (+) connected to an output terminal 13b of the inverting amplifier 13 and an inverting input terminal (−) connected to a reference power source 15 configured to output a predetermined reference voltage Vref. The comparator 16 compares the output voltage Vo of the inverting amplifier 13 with the reference voltage Vref, and outputs either a high-level or low-level voltage Vout according to the result of the comparison.

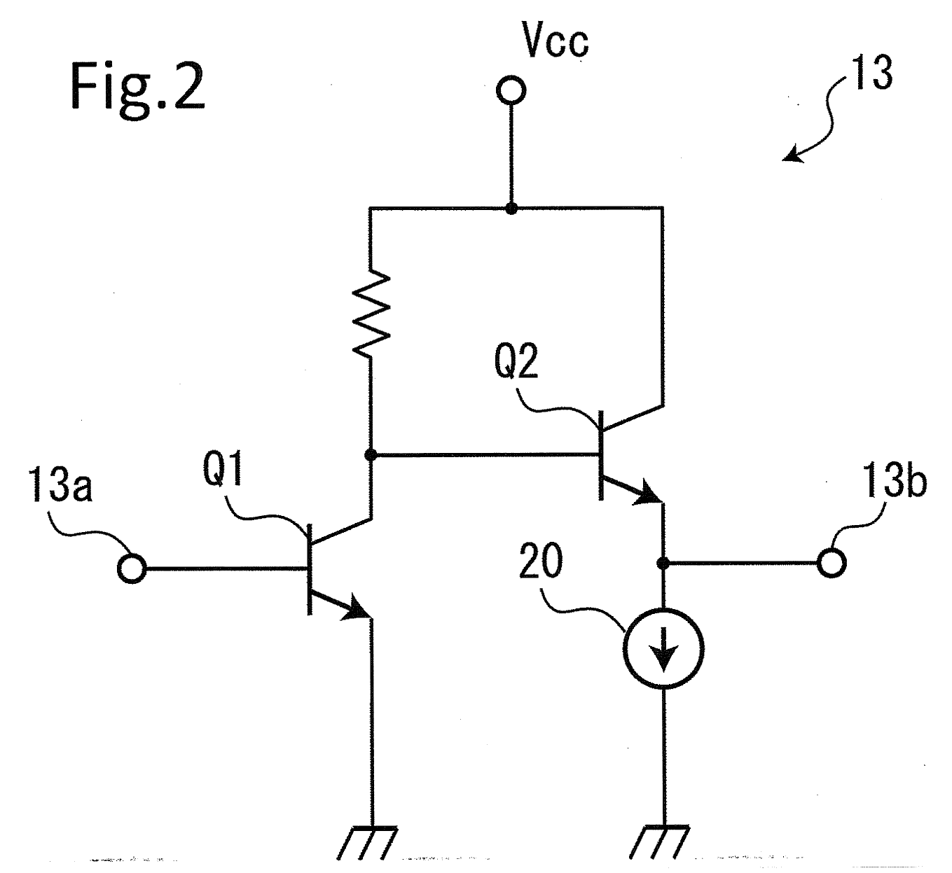

FIG. 2 is a circuit diagram illustrating the circuit configuration of the inverting amplifier 13. As FIG. 2 shows, the inverting amplifier 13 at least includes an npn bipolar transistor Q1 (hereinafter, referred to as the transistor Q1), an npn bipolar transistor Q2 (hereinafter, referred to as the transistor Q2), a resistor R4, and a constant current source 20.

The transistor Q1 has a base connected to the light receiving element 12, a collector connected to the resistor R4, which is connected to a power source Vcc, and an emitter connected to the ground. The transistor Q2 has a base connected to the collector of the transistor Q1, a collector connected to the power source Vcc, and an emitter connected to the constant current source 20, which is connected to the ground.

The transistor Q1 is an emitter-grounded amplifier whereas the transistor Q2 is a collector-grounded amplifier with a voltage amplification of approximately one.

The light receiving element 12 outputs a current Ip according to the intensity of the received input light 11, and supplies the output current Ip to the inverting amplifier 13, that is, to the base of the transistor Q1. The transistor Q1 converts the current Ip to a voltage and amplifies the voltage thus obtained. The transistor Q2 outputs the output voltage of the transistor Q1 as a low-impedance signal to the output terminal 13b. The light receiving element 12 may be a silicon photo diode, an InGaAs PIN photo diode, or an avalanche photo diode, depending upon the wavelength of the input light 11.

The feedback circuit 14 includes a first resistor R1, a second resistor R2 that has the same resistance as that of the first resistor R1, a third resistor R3, a first capacitor C1, and a correction circuit 18, all of which are provided between the input terminal 13a of the inverting amplifier 13 and the output terminal 13b thereof.

The first resistor R1 and the second resistor R2 provided between the input terminal 13a of the inverting amplifier 13 and the output terminal 13b thereof are connected in series to each other at a connection point 17. The third resistor R3 and the first capacitor C1 connected in series are connected between the connection point 17 and the ground. In the case shown in FIG. 1, a first terminal of the third resistor R3 is connected to the connection point 17, and a second terminal of the third resistor R3 is connected to the first capacitor C1, which is connected to the ground.

In this embodiment, the correction circuit 18 is connected between the connection point 17 and the ground in parallel to both the third resistor R3 and the first capacitor C1.

In the correction circuit 18, a fourth resistor R4 and a second capacitor C2 are connected to each other between the connection point 17 and the ground. In the case shown in FIG. 1, a first terminal of the fourth resistor R4 is connected to the connection point 17, and a second terminal of the fourth resistor R4 is connected to the second capacitor C2, which is connected to the ground.

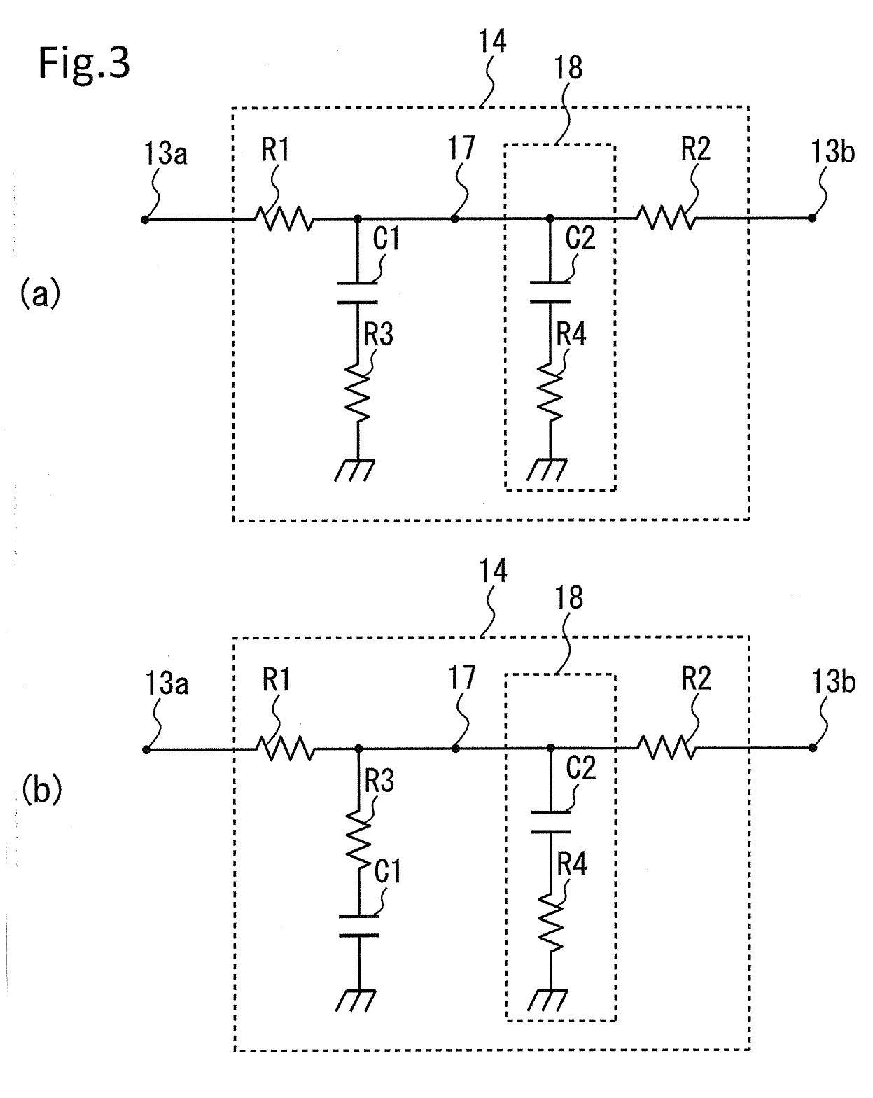

FIG. 3 is circuit diagrams illustrating a feedback circuit 14 according to some modifications of the first embodiment. As FIG. 3 shows, the positions of a capacitor and a resistor provided in the feedback circuit 14 may be switched. For instance, as FIG. 3A shows, it is allowable that a first capacitor C1 is connected to a connection point 17, a first terminal of a third resistor R3 is connected to the first capacitor C1, and a second terminal of the third resistor R3 is connected to the ground. Likewise, it is allowable that a second capacitor C2 is connected to the connection point 17, a first terminal of a fourth resistor R4 is connected to the second capacitor C2, and a second terminal of the fourth resistor R4 is connected to the ground.

Alternatively, the positions of the third resistor R3 and the first capacitor C1 may be not only line-symmetric but also point-symmetric to the positions of the fourth resistor R4 and the second capacitor. For instance, as FIG. 3B shows, it is allowable that a first terminal of a third resistor R3 is connected to a connection point 17, a second terminal of the third resistor R3 is connected to a first capacitor C1, and the first capacitor C1 is connected to the ground. Likewise, it is allowable that a second capacitor C2 is connected to the connection point 17, a first terminal of a fourth resistor R4 is connected to the second capacitor C2, and a second terminal of the fourth resistor R4 is connected to the ground.

Description is given below of the impedance of the feedback circuit 14.

In the following description, it is assumed that the emitter-grounded amplifier implemented by the transistor Q1 has a sufficiently large gain, e.g., equal to 50 or larger.

In addition, the junction capacitance of the light receiving element 12 is assumed to be negligible, and the inverting amplifier 13 is assumed to be an ideal amplifier that is frequency-independent.

Moreover, the transimpedance characteristics of the inverting amplifier 13 and the feedback circuit 14 are assumed to be equal to the transimpedance characteristics |Zf| of the feedback circuit 14.

The output voltage signal Vo of the inverting amplifier 13 is obtained by the following equation: V0=Ip×|Zf|. Accordingly, the transimpedance characteristics of the inverting amplifier 13 are expressed by the transfer function |Zf| of the following equation, where s is the Laplace operator, that is, the Laplace plane.

$$[ Numerical Expression 1 ]$$

$$\vert {Z}_{f} \vert = \vert \frac{{v}_{0}}{{i}_{p}} \vert = \vert {R}_{0} \cdot \frac{\begin{matrix}( 2 + \frac{{R}_{0}}{{R}_{3}} + \frac{{R}_{0}}{{R}_{4}} ) \cdot {s}^{2} + \\ ( \frac{2}{{C}_{1} {R}_{3}} + \frac{2}{{C}_{2} {R}_{4}} + \frac{{R}_{0}}{{C}_{1} {R}_{3} {R}_{4}} + \frac{{R}_{0}}{{C}_{2} {R}_{3} {R}_{4}} ) \cdot s + \frac{2}{{C}_{1} {C}_{2} {R}_{3} {R}_{4}}\end{matrix}}{( s + \frac{1}{{C}_{1} {R}_{3}} ) \cdot ( s + \frac{1}{{C}_{2} {R}_{4}} )} \vert$$

For the sake of explanatory simplicity, in the equation above, the resistances of the first resistor R1 and that of the second resistor R2 are expressed as R0=R1=R2=R; the capacitance of the first capacitor C1 and the resistance of the first resistor R1 are expressed as C1R1=t0; and the capacitance of the second capacitor C2 and the resistance of the second resistor R2 are expressed as C2R2=t2. Then, the transimpedance characteristics |Zf| is expressed by the following equation.

$$\vert {Z}_{f} \vert = \vert \frac{{v}_{0}}{{i}_{p}} \vert = \vert 2 R \cdot \frac{2 {s}^{2} + \frac{3}{2} ( \frac{1}{{t}_{0}} + \frac{1}{{t}_{2}} ) \cdot s + \frac{1}{{t}_{0} {t}_{2}}}{( s + \frac{1}{{t}_{0}} ) \cdot ( s + \frac{1}{{t}_{2}} )} \vert \qquad [ Numerical Expression 2 ]$$

Furthermore, it is assumed that t0=α·t2=t, and α>1.

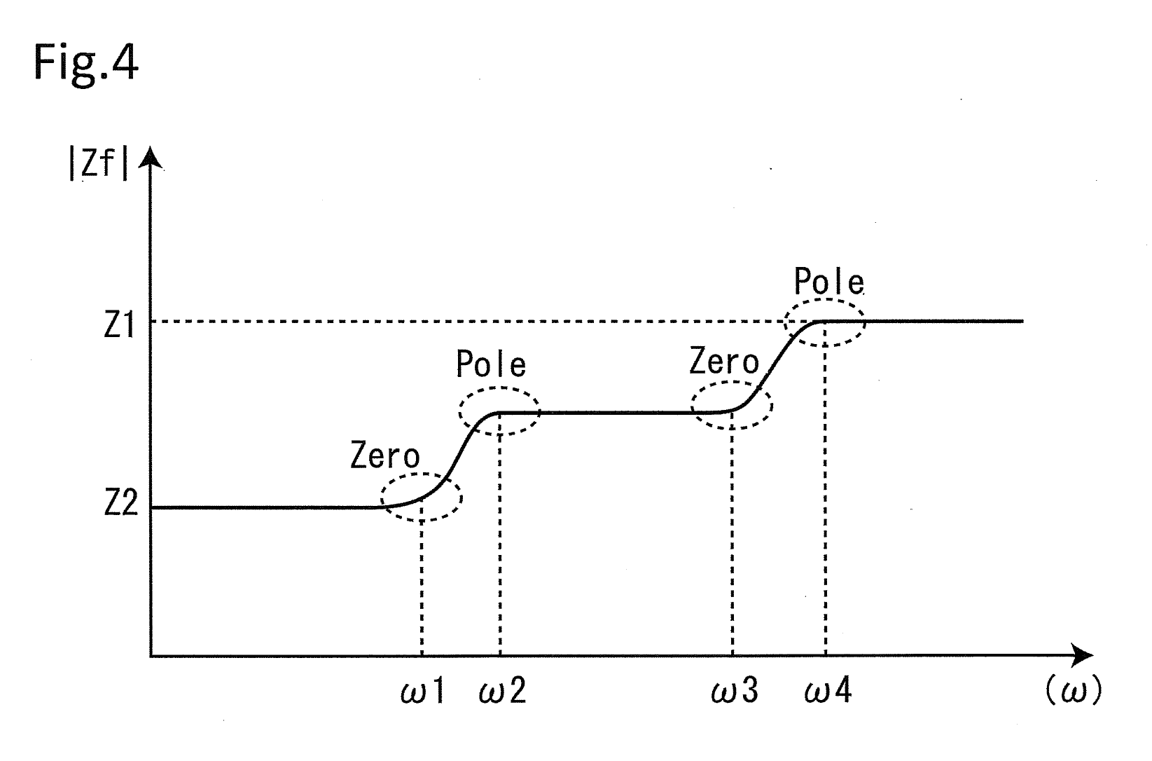

FIG. 4 is a graph showing the transimpedance characteristics of the inverting amplifier 13 according to the embodiment. The horizontal axis represents the angular frequency ω, and the vertical axis represents the transimpedance characteristics |Zf|. In general, if the transimpedance characteristics |Zf| are expressed by a transfer function G(s), a root of the equation of the transfer function with the numerator being 0 is referred to as a zero, and a root of the equation of the transfer function with the denominator being 0 is referred to as a pole.

As FIG. 4 shows, with the circuit configuration of this first embodiment, there are two pairs of a zero and a pole. Hence, the first root of the numerator is expressed as ω1, the first root of the denominator is expressed as ω2, the second root of the numerator is expressed as ω3, and the second root of the denominator is expressed as ω4.

The occurrence of the two pairs of a zero and a pole is expressed below by a numerical expression. Note that the resistances of the first resistor R1 and the second resistor R2 are expressed as R1=R2=R0 for the convenience sake.

Assuming that the root of the equation of the transfer function of Numerical Expression 1 with the numerator being 0 is zero, and that the root of the equation with the denominator being 0 is pole, the zero and the pole are expressed by the following expressions.

$$pole \text{:} - \frac{1}{t} , - \frac{α}{t} \\ zero \text{:} \frac{- 3}{8 t} [ ( α + 1 ) \pm \sqrt{{α}^{2} - \frac{14}{9} α + 1} ] \qquad [ Numerical Expression 3 ]$$

Since the expression in the root sign of the expression representing the zero can be rewritten into the following expression and always has a positive value, it is not necessary to consider that the square root becomes an imaginary number.

$$\sqrt{{α}^{2} - \frac{14}{9} α + 1} = \sqrt{{( α - 1 )}^{2} + \frac{4}{9} α} \qquad [ Numerical Expression 4 ]$$

To make a zero, a pole, a zero, and a pole appear in this sequence from the origin towards −∞ on the negative real axis requires that all the following equations A to D have positive values.

$$A = 0 - ( - \frac{3}{8 t} [ ( α + 1 ) - \sqrt{{α}^{2} - \frac{14}{9} α + 1} ] ) \\ B = - \frac{3}{8 t} [ ( α + 1 ) - \sqrt{{α}^{2} - \frac{14}{9} α + 1} ] - ( - \frac{1}{t} ) \\ C = - \frac{1}{t} - ( - \frac{3}{8 t} [ ( α + 1 ) + \sqrt{{α}^{2} - \frac{14}{9} α + 1} ] ) \\ D = - \frac{3}{8 t} [ ( α + 1 ) + \sqrt{{α}^{2} - \frac{14}{9} α + 1} ] - ( - \frac{α}{t} ) \qquad [ Numerical Expression 5 ]$$

If it is positive in [ ] because it is that t has positive (t>0) for equation n A, equation A has positive (A>0). That is, if clause 1 and clause 2 are done respectively by the second power, and subtracted, equation A has positive (A>0). Because both clause 1 and clause 2 in [ ] have positive.

$${( α + 1 )}^{2} - {( \sqrt{{α}^{2} - \frac{14}{9} α + 1} )}^{2} = \frac{32}{9} α > 0 \qquad [ Numerical Expression 6 ]$$

The positive and negative can be judged by doing equation B by 8t/3 time because t has positive (t>0) for equation B

$$\frac{8 t}{3} B = \sqrt{{α}^{2} - \frac{14}{9} α + 1} + ( \frac{5}{3} - α ) \qquad [ Numerical Expression 7 ]$$

If 1<α≦5/3, equation B has positive (B>0) because clause 2 of the Numerical Expression 7 has positive. In addition, if α>5/3, clause 2 of the Numerical Expression 7 has negative. Hence, if clause 1 and clause 2 of the Numerical Expression 7 is done by the second power, and of each is subtracted, it becomes Numerical Expression 8. In this case, equation B has positive (B>0).

$${α}^{2} - \frac{14}{9} α + 1 - ( {α}^{2} - \frac{30}{9} α + \frac{25}{9} ) = \frac{16}{9} α - \frac{16}{9} > 0 \qquad [ Numerical Expression 8 ]$$

The positive and negative can be judged by doing equation C in 8t/3 time because it is t>0 for equation C.

$$\frac{8 t}{3} C = \sqrt{{α}^{2} - \frac{14}{9} α + 1} + ( α - \frac{5}{3} ) \qquad [ Numerical Expression 9 ]$$

If α≧5/3, Clause 2 of the Numerical Expression 9 has positive. Hence, equation C has a positive value (C>0).

In addition, if 1<α<5/3, Clause 2 of the Numerical Expression 9 has negative. Numerical Expression 10 consists when each paragraph is done by the second power and it subtracts it mutually. In this case, equation C has positive (C>0).

$${α}^{2} - \frac{14}{9} α + 1 - ( {α}^{2} - \frac{30}{9} α + \frac{25}{9} ) = \frac{16}{9} α - \frac{16}{9} > 0 \qquad [ Numerical Expression 10 ]$$

The positive and negative can be judged by doing equation D in 8t/3 time because t has positive (t>0) for equation D.

$$\frac{8 t}{3} D = ( \frac{5}{3} α - 1 ) - \sqrt{{α}^{2} - \frac{14}{9} α + 1} \qquad [ Numerical Expression 11 ]$$

Expression 12 holds when clause 1 and 2 is done respectively by the second power and it subtracts it because clause 1 becomes always positive. In this case, equation D has positive (D>0).

$$\frac{16}{9} {α}^{2} - \frac{16}{9} α > 0 \qquad [ Numerical Expression 12 ]$$

Accordingly, it is revealed that all the values A to D of Numerical Expression 5 are larger than 0. Hence, under the above-mentioned conditions, zeros and poles are on the negative real axis of the Laplace plane(s), and the first zero, the first pole, the second zero, and the second pole appear alternately in this sequence from the origin in the negative direction.

### Comparative Example

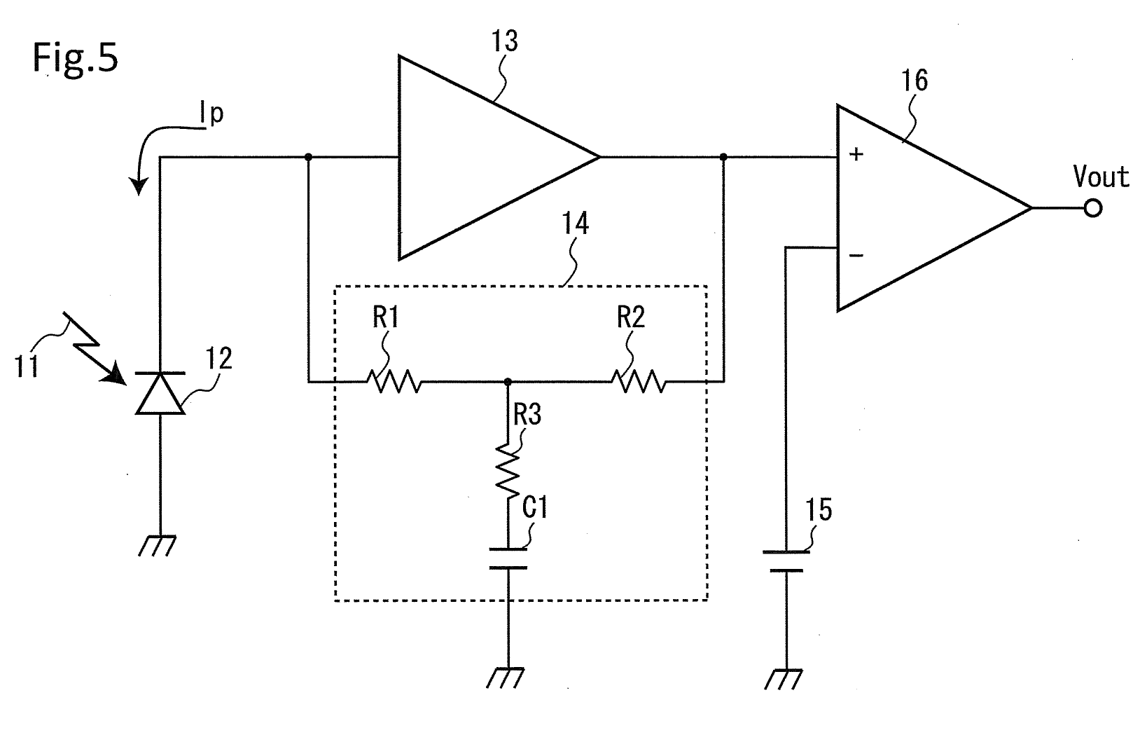

FIG. 5 is a circuit diagram of a comparative example. A feedback circuit 14 of the comparative example forms what is known as a T-shaped network, where a third resistor R3 and a first capacitor C1 are provided between a ground potential Gnd and the connection point of a first resistor R1 to a second resistor R2. The feedback circuit 14 has transimpedance characteristics that vary depending upon the frequency. Specifically, since a feedback circuit 14 includes the third resistor R3 and the first capacitor C1 which is connected in series to the third resistor R3, the feedback circuit 14 has smaller transimpedance on the low-frequency side and larger transimpedance on the high-frequency side.

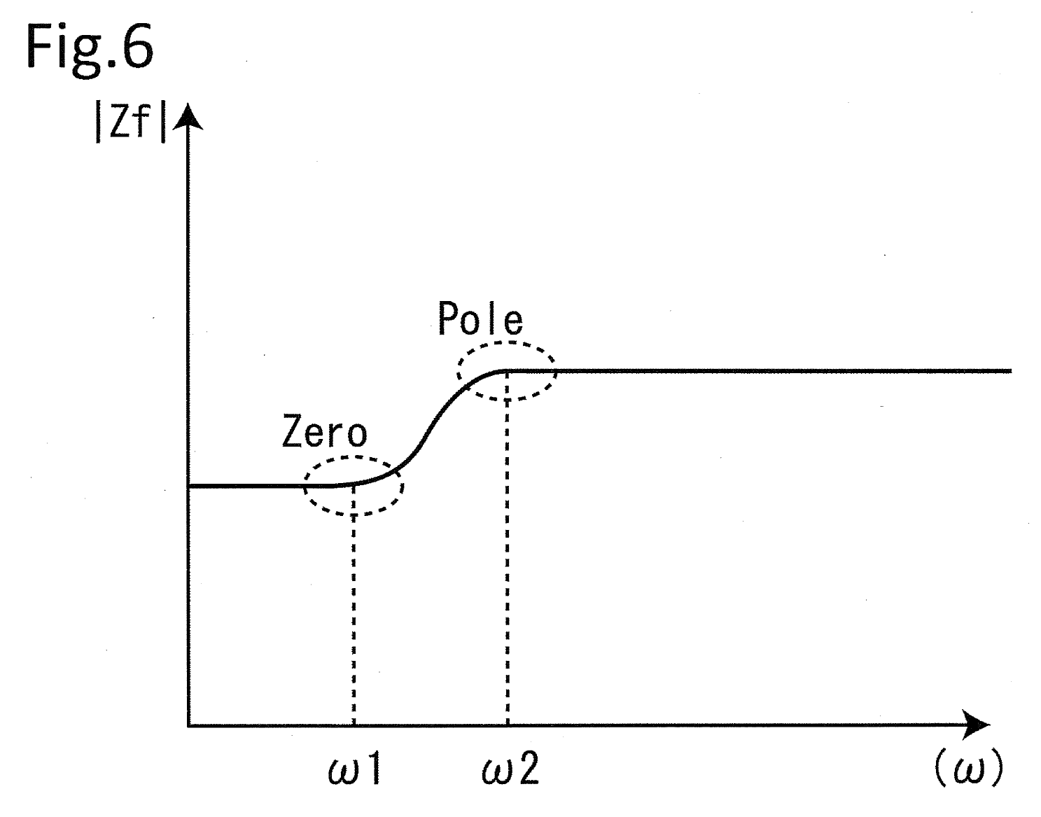

FIG. 6 is a graph showing the frequency response of an inverting amplifier 13 of the comparative example. The horizontal axis represents the angular frequency ω, and the vertical axis represents the current-voltage characteristics Vo/Ip, that is, the transimpedance characteristics |Zf|. The transimpedance characteristics reveal that, with the circuit configuration of the comparative example, there is only a single pair of a zero and a pole that occur at angular frequencies ω1 and ω2.

If, however, the optical receiver circuit is put into practical use under the conditions that there are a plurality of band-limiting factors, such as the frequency characteristics of the input light and the influences of the carriers diffused in the light receiving element, the configuration of the comparative example has only insufficient effects to correct the pulse distortion and causes, in some cases, malfunctions, which will be described later.

Accordingly, the optical receiver circuit of this first embodiment is configured to have frequency characteristics such that a higher gain is obtained in a high-frequency band though the frequency characteristics are impaired at the output terminal 13b due to the influence of both the input light and the carriers diffused in the light receiving element.

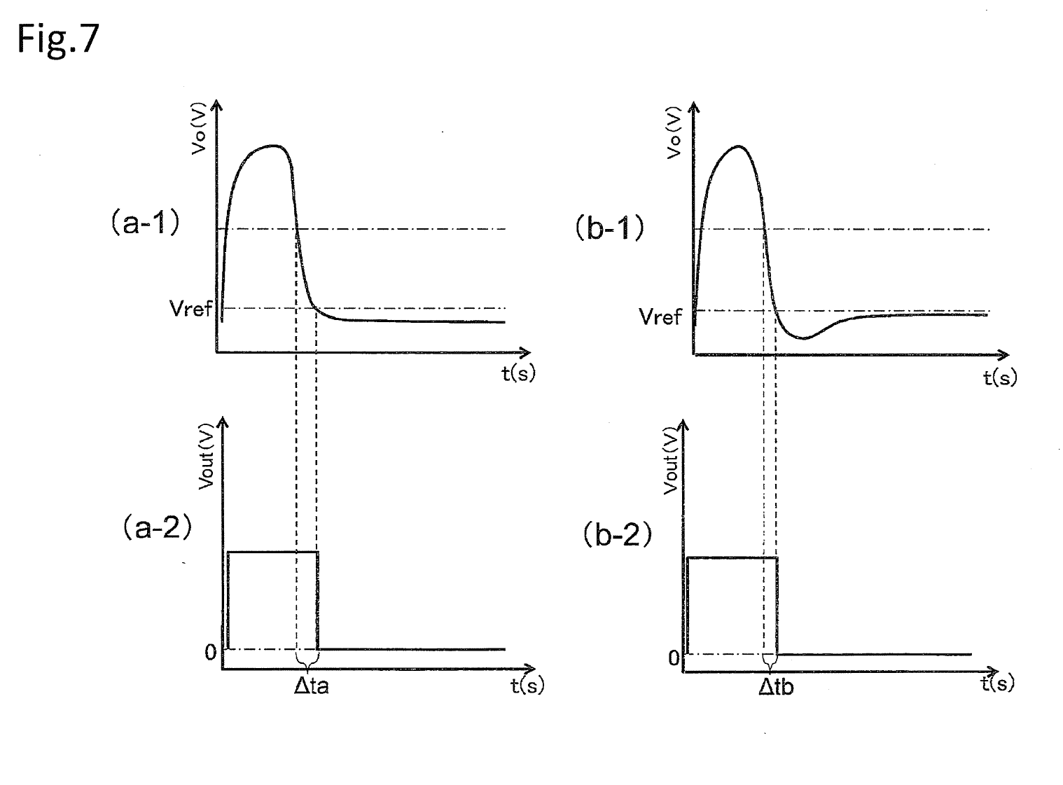

FIG. 7 is timing charts illustrating waveforms of the pulse signals of the first comparative example and those of this first embodiment. In the case shown in FIG. 7, it is assumed that the pulse width is 100 ns; the time constant t1 due to the diffused carriers in the PD is 3 us; the time constant t2 of the response characteristics for the LED is 20 ns; and the fall of the gain due to the diffused carries in the PD is 20%. In addition, the resistances and the capacitances in the case of FIG. 7 are such that R1=R2=R3=R4=R, C1=100 pF, R=10 kΩ, and C2=6 pF.

FIGS. 7A-1 and 7A-2 show the pulse waves of the comparative example. FIG. 7A-1 shows the output Vo of the inverting amplifier 13. FIG. 7A-2 shows the output Vout of a comparator 16. These graphs reveal that, in the comparative example, the waveform of the output Vo of the inverting amplifier 13 is trailing so that a time delay corresponding to Δta occurs and distortion of the pulse width (specifically, the widening of the pulse width) occurs in the output Vout of the comparator 16.

In contrast, FIGS. 7B-1 and 7B-2 show the pulse waves of this first embodiment. FIG. 7B-1 shows the output Vo of the inverting amplifier 13. FIG. 7B-2 shows the output Vout of the comparator 16. In this first embodiment, an undershooting is made to occur at the tail of the wave of the output Vo of the inverting amplifier 13 as shown in FIG. 7B-1. In this case, as FIG. 7B-2 shows, a certain time delay Δtb occurs both at the rising of the pulse wave and at the falling thereof, but the undershooting that is intentionally caused makes the time delay Δtb shorter than the time delay Δta (i.e., Δta>Δtb). Accordingly, it is possible to reduce both the time delay and the distortion of the pulse width.

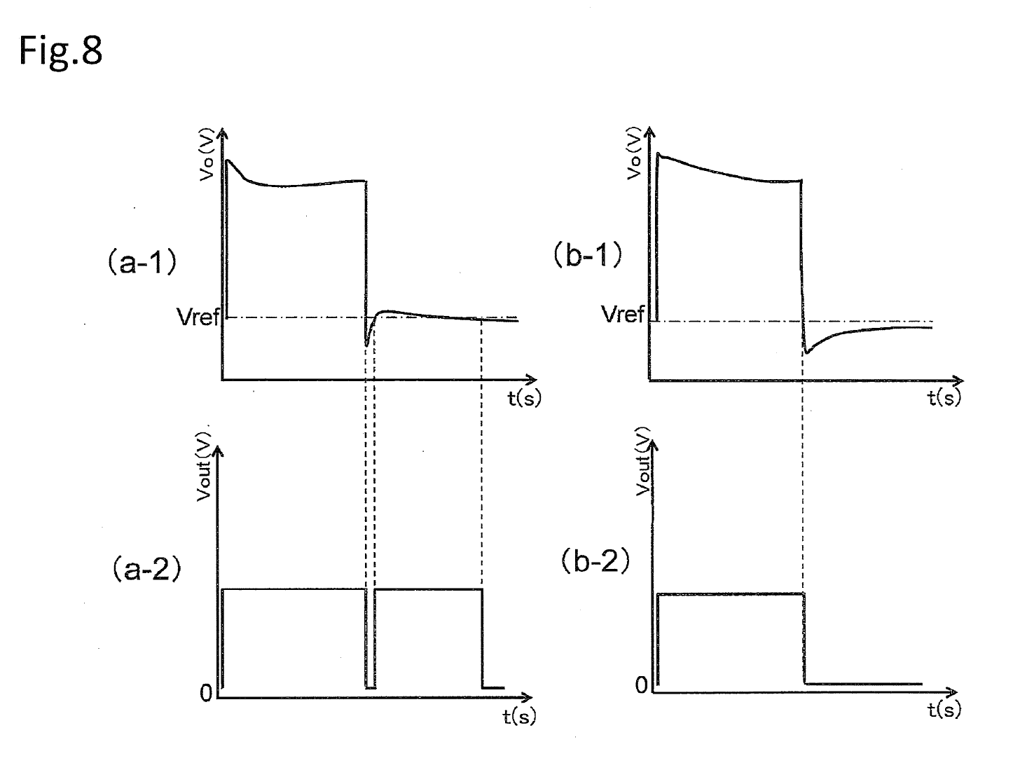

FIG. 8 is timing charts illustrating waveforms of the pulse signals of the first comparative example and those of this first embodiment. The timing charts shown in FIG. 8 are of a case where the pulse width is 1 us. The resistances and the capacitances in the case of FIG. 8 are such that R1=R2=R3=R4=R0, C1=100 pF, R=10 kΩ, and C2=6 pF.

In the case shown in FIG. 8, it is assumed that the time constant t1 due to the diffused carriers in the PD is 3 us; the time constant t2 of the response characteristics for the LED is 20 ns; and the fall of the gain due to the diffused carries in the PD is 20%.

FIGS. 8A-1 and 8A-2 show the pulse waves of the comparative example. FIG. 8A-1 shows the output Vo of the inverting amplifier 13. FIG. 8A-2 shows the output Vout of the comparator 16. These graphs reveal that, in the comparative example, the tail of the wave after the falling of the output Vo of the inverting amplifier 13 is lifted up above the reference voltage Vref, so that an error output occurs in the output Vout of the comparator 16.

In contrast, FIGS. 8B-1 and 8B-2 show the pulse waves of this first embodiment. FIG. 8B-1 shows the output Vo of the inverting amplifier 13. FIG. 8B-2 shows the output Vout of the comparator 16. As FIG. 8B-1 shows, in this first embodiment, an undershooting is made to occur at the tail of the wave of the output Vo of the inverting amplifier 13, so that the output Vo of the inverting amplifier 13 can be not higher than the reference voltage Vref at the next rising. The undershooting that is intentionally caused to control the tail of the wave in the above-described manner makes it possible to prevent an error output of the output signal Vout from occurring as shown in FIG. 8B-2.

### Second Embodiment

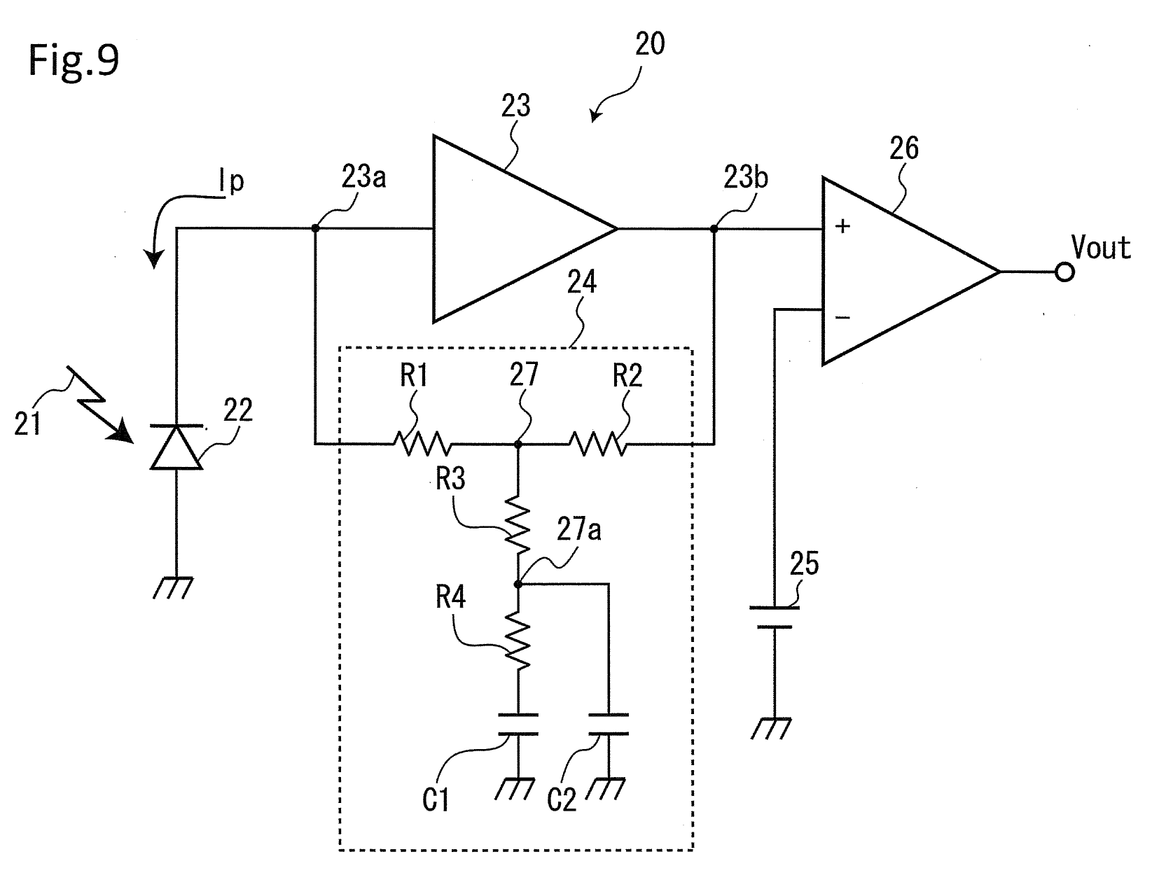

FIG. 9 is a circuit diagram illustrating an optical receiver circuit 20 according to the second embodiment. As FIG. 9 shows, the optical receiver circuit 20 of this second embodiment includes a feedback circuit 24, which distinguishes the second embodiment from the first embodiment. Specifically, a third resistor R3, a fourth resistor R4, and a first capacitor C1 are connected in series between a ground and a connection point 27 of a first resistor R1 to a second resistor R2. In addition, a second capacitor C2 is connected between a ground and a connection point 27a of the third resistor R3 to the fourth resistor R4.

Note that, also in this second embodiment, the resistance of the first resistor R1 is equal to the resistance of the second resistor R2.

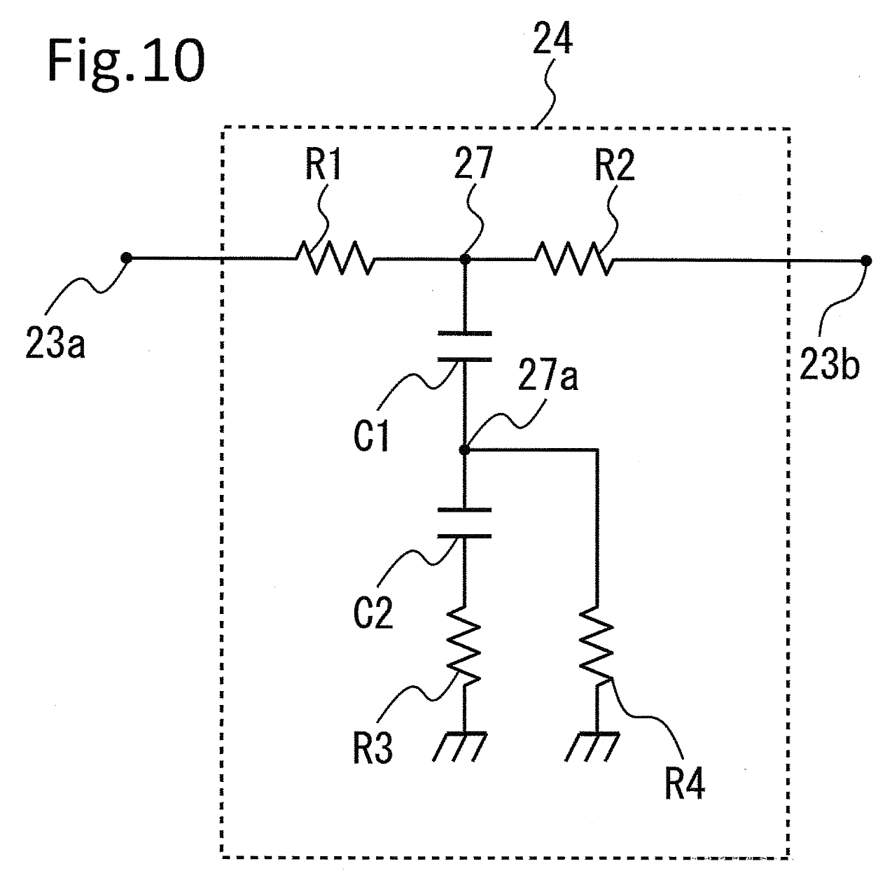

FIG. 10 is a circuit diagram illustrating a feedback circuit 24 according to a modification of the second embodiment. As FIG. 10 shows, the positions of the resistors and those of the capacitors may be switched from the case shown in FIG. 9. For instance, a first capacitor C1, a second capacitor C2, and a third resistor R3 are connected in series between a ground and a connection point 27 of a first resistor R1 to a second resistor R2. In addition, a fourth resistor R4 is connected between a ground and a connection point of the first capacitor C1 to the second capacitor C2.

An inverting amplifier 23 according to this second embodiment shows transimpedance characteristics |Zf| with two pairs of a pole and a zero as with the graph of FIG. 4 according to the first embodiment.

The occurrence of the two pairs of a zero and a pole is expressed below by a numerical expression. Note that the resistances of the first resistor R1 and the second resistor R2 are expressed as R1=R2=R0 for the convenience sake.

If the junction capacitance of a light receiving element 22 is assumed to be negligible, and the inverting amplifier 23 is assumed to be an ideal amplifier that is frequency-independent, the transimpedance characteristics |Zf| of the inverting amplifier 23 are expressed by the following Numerical Expression 13 by using the Laplace transform.

$$[ Numerical Expression 13 ]$$

$$\vert {Z}_{f} \vert = \vert \frac{{v}_{0}}{{i}_{p}} \vert = \vert {R}_{0} \cdot \frac{{s}^{2} [ {C}_{1} {C}_{2} {R}_{4} ( {R}_{0} + 2 {R}_{3} ) ] + s [ ( {R}_{0} + 2 {R}_{3} ) ( {C}_{1} + {C}_{2} ) + 2 {C}_{2} {R}_{4} ] + 2}{{s}^{2} {C}_{1} {C}_{2} {R}_{3} {R}_{4} + s ( {C}_{2} {R}_{4} + {C}_{2} {R}_{3} + {C}_{1} {R}_{3} ) + 1} \vert$$

In this second embodiment, a transfer function with two pairs of a zero and a pole is obtained as with the case of the first embodiment. Hence, if the roots of the denominator of Numerical Expression 13 and the roots of the numerator thereof are calculated, the first root ω1 of the numerator, the first root ω2 of the denominator, the second root ω3 of the numerator, and the second root ω4 of the denominator can be obtained.

This second embodiment describes a case where there are two pairs of a pole and a zero as an example, but this is not the only possible case. For instance, by providing the configuration shown in FIG. 9 with a plurality of pairs of the third resistor R3 and the second capacitor C2 between the connection point 27 and the ground, three or more pairs of a pole and a zero can be made to occur.

Accordingly, if three or more pairs of a pole and a zero are made to occur, the delay time in a comparator 16 can be shortened and error in the output pulse Vout can be reduced.

### Third Embodiment

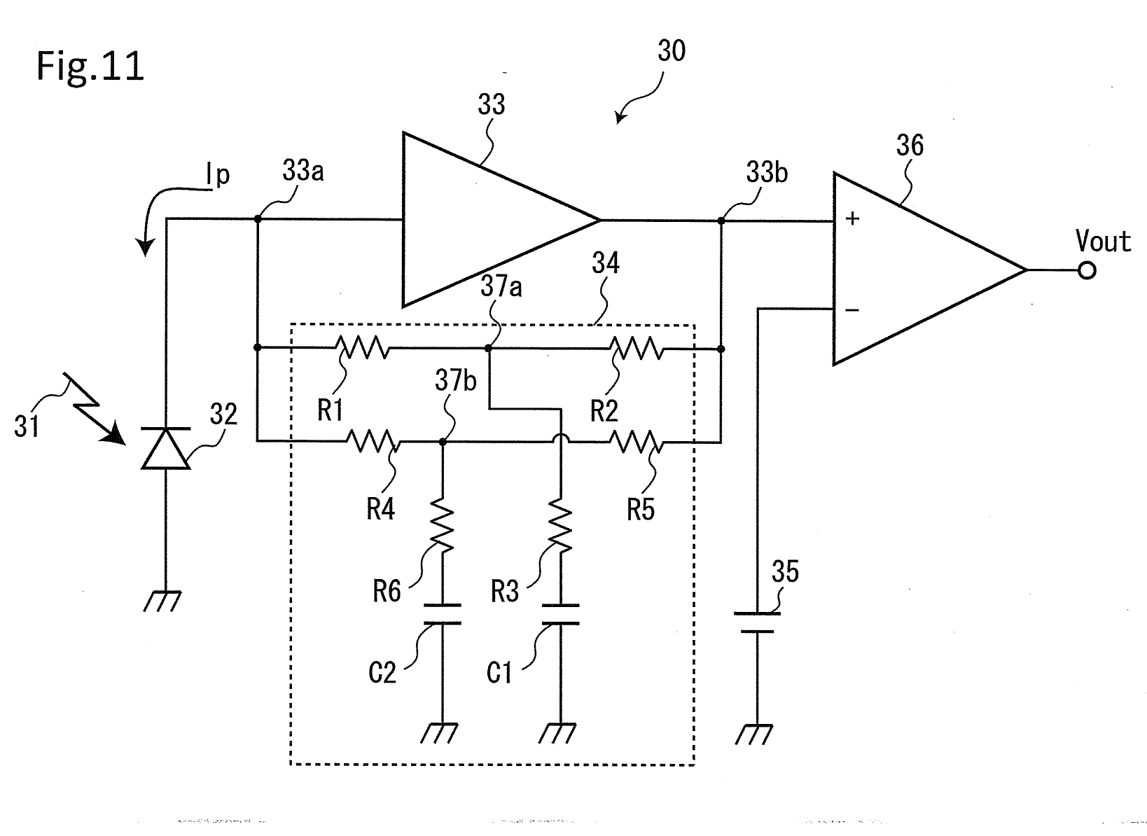

FIG. 11 is a circuit diagram illustrating an optical receiver circuit 30 according to a third embodiment. As FIG. 11 shows, the optical receiver circuit 30 of this third embodiment includes a feedback circuit 34, which distinguishes this third embodiment from the first embodiment. Specifically, a first resistor R1 and a second resistor R2 are connected in series between an input terminal 33a and an output terminal 33b. In addition, a third resistor R3 and a first capacitor C1 are connected in series between a ground and a connection point 37a of the first resistor R1 to the second resistor R2. Moreover, a fourth resistor R4 and a fifth resistor R5 are connected in series between the input terminal 33a and the output terminal 33b so that the fourth resistor R4 and the fifth resistor R5 can be parallel to the first resistor R1 and the second resistor R2. Furthermore, a sixth resistor R6 and a second capacitor C2 are to each other between a ground and a connection point 37b of the fourth resistor R4 to the fifth resistor R5.

In this third embodiment, the resistances of the first resistor R1, the second resistor R2, the fourth resistor R4, and the fifth resistor R5 are equal to one another.

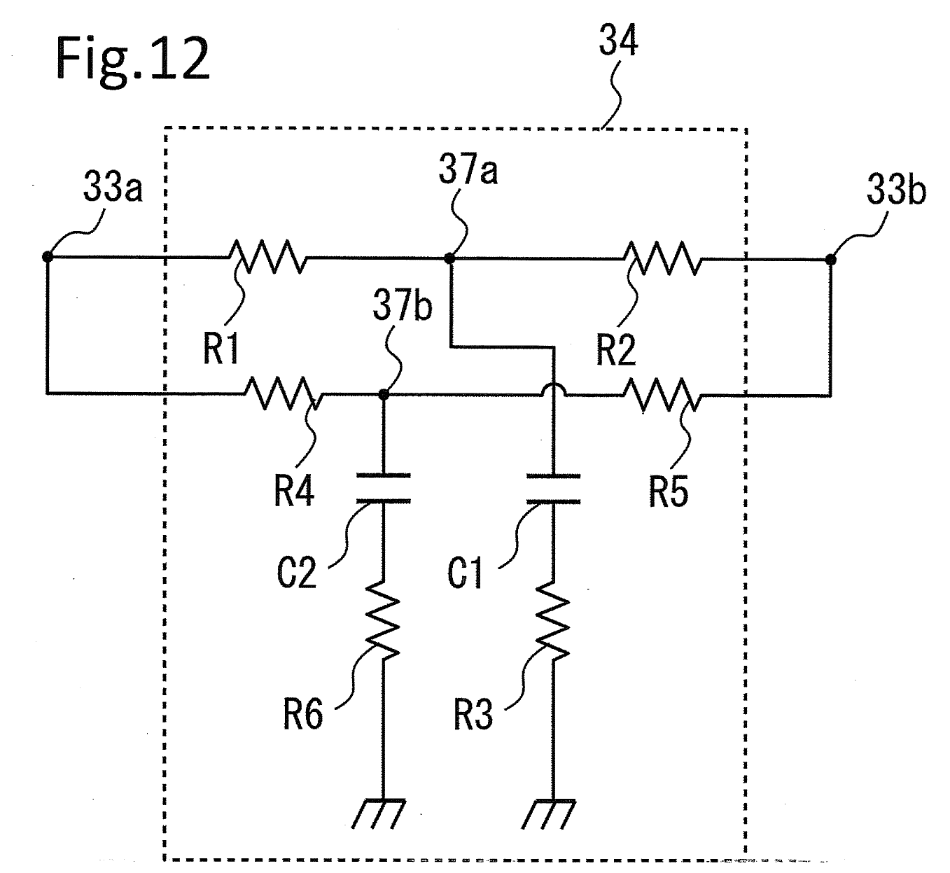

FIG. 12 is a circuit diagram illustrating a feedback circuit 34 according to a modification of the third embodiment. As FIG. 12 shows, the positions of the resistors and those of the capacitors may be switched from the case shown in FIG. 11. For instance, it is allowable that a first capacitor C1 is connected to a connection point 37a, a first terminal of a third resistor R3 is connected to the first capacitor C1, and a second terminal of the third resistor is connected to the ground. Likewise, it is allowable that a second capacitor C2 is connected to a connection point 37b, a first terminal of a sixth resistor R6 is connected to the second capacitor C2, and a second terminal of the sixth resistor R6 is connected to the ground.

An inverting amplifier 33 according to this third embodiment shows transimpedance characteristics |Zf| with two pairs of a pole and a zero as with the graph of FIG. 4 according to the first embodiment.

The occurrence of the two pairs of a zero and a pole is expressed below by a numerical expression. Note that the resistances of the first resistor R1, the second resistor R2, the fourth resistor R4, and the fifth resistor R5 are such that R1=R2=R4=R5=R0 for the convenience sake.

If the junction capacitance of a light receiving element 32 is assumed to be negligible, and the inverting amplifier 33 is assumed to be an ideal amplifier that is frequency-independent, the transimpedance characteristics |Zf| of the inverting amplifier 33 are expressed by the following Numerical Expression 14 by using Laplace transform.

$$[ Numerical Expression 14 ]$$

$$\vert {Z}_{f} \vert = \vert \frac{{v}_{0}}{{i}_{p}} \vert = \vert {R}_{0} \cdot \frac{\begin{matrix}{s}^{2} {C}_{1} {C}_{2} [ {R}_{0} ( {R}_{0} + 2 {R}_{6} + 2 {R}_{3} ) + 4 {R}_{3} {R}_{6} ] + \\ s [ 2 {R}_{0} ( {C}_{1} + {C}_{2} ) + 4 ( {C}_{2} {R}_{6} + {C}_{1} {R}_{3} ) ] + 4\end{matrix}}{\begin{matrix}{s}^{2} {C}_{1} {C}_{2} ( {R}_{3} {R}_{0} + {R}_{6} {R}_{0} + 4 {R}_{3} {R}_{6} ) + \\ s ( 4 {C}_{1} {R}_{3} + 4 {C}_{2} {R}_{6} + {C}_{1} {R}_{0} + {C}_{2} {R}_{0} ) + 4\end{matrix}} \vert$$

In this third embodiment, a transfer function with two pairs of a zero and a pole is obtained as with the case of the first embodiment. Hence, if the roots of the denominator of Numerical Expression 14 and the roots of the numerator thereof are calculated, the first root ω1 of the numerator, the first root ω2 of the denominator, the second root ω3 of the numerator, and the second root ω4 of the denominator can be obtained.

This third embodiment describes a case where there are two pairs of a pole and a zero as an example, but this is not the only possible case. For instance, by providing the configuration shown in FIG. 11 with a plurality of sets of the fourth resistor R4, the fifth resistor R5, the sixth resistor R6, and the second capacitor C2 between the connection point 33a and the connection point 33b, three or more pairs of a pole and a zero can be made to occur.

Accordingly, if three or more pairs of a pole and a zero are made to occur, the delay time in a comparator 36 can be shortened.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An optical receiver circuit comprising:
light receiving means configured to output a current according to input light;
an inverting amplifier having an input terminal and an output terminal, the input terminal connected to the light receiving means;
a feedback circuit connected between the input terminal and the output terminal, and provided with a plurality of pairs of a pole and a zero on a negative real axis on a Laplace plane so that transimpedance characteristics show high gains of a plurality of steps on high-frequency side.

2. The optical receiver circuit according to claim 1, wherein the plurality of pairs of a pole and a zero are such that the zeros and the pole are alternately arranged on the negative real axis of the Laplace plane in a sequence starting with zero and ending with pole from an origin in a negative direction.

3. The optical receiver circuit according to claim 1, further comprising a comparator having a first input terminal connected to the output terminal of the inverting amplifier, and a second input terminal connected to a reference power source.

4. The optical receiver circuit according to claim 1, wherein
the feedback circuit includes:
a first resistor and a second resistor that are connected in series between the input terminal of the inverting amplifier and the output terminal of the inverting amplifier;
a third resistor and a first capacitor that are connected in series to each other between a ground and a connection point of the first resistor to the second resistor; and
a correction circuit connected between a ground and the connection point of the first resistor to the second resistor and connected in parallel to the third resistor and the first capacitor.

5. The optical receiver circuit according to claim 4, wherein the correction circuit includes a resistor and a capacitor.

6. The optical receiver circuit according to claim 1, wherein
the feedback circuit includes:
a first resistor and a second resistor that are connected in series between the input terminal of the inverting amplifier and the output terminal of the inverting amplifier;
a third resistor, a fourth resistor, and a first capacitor that are connected in series to one another between a ground and a connection point of the first resistor to the second resistor; and
a second capacitor connected between a ground and a connection point of the third resistor to the fourth resistor.

7. The optical receiver circuit according to claim 1, wherein
the feedback circuit includes:
a first resistor and a second resistor that are connected in series between the input terminal of the inverting amplifier and the output terminal of the inverting amplifier;
a first capacitor, a second capacitor, and a third resistor that are connected in series to one another between a ground and a connection point of the first resistor to the second resistor; and
a fourth resistor connected between a ground and a connection point of the first capacitor to the second capacitor.

8. The optical receiver circuit according to claim 1, wherein
the feedback circuit includes:
a first resistor and a second resistor that are connected in series between the input terminal of the inverting amplifier and the output terminal of the inverting amplifier;
a third resistor and a first capacitor that are connected in series between a ground and a connection point of the first resistor to the second resistor;
a fourth resistor and a fifth resistor that are connected between the input terminal of the inverting amplifier and the output terminal of the inverting amplifier so that the fourth resistor and the fifth resistor are parallel to the first resistor and the second resistor; and
a sixth resistor and a second capacitor that are connected in series between a ground and a connection point of the fourth resistor to the fifth resistor.

9. An optical receiver circuit comprising:
a light receiving element configured to output a current according to input light;
an inverting amplifier having an input terminal and an output terminal, the input terminal connected to the light receiving element;
a first resistor and a second resistor that are connected in series between the input terminal of the inverting amplifier and the output terminal of the inverting amplifier;
a third resistor and a first capacitor that are connected in series to each other between a ground and a connection point of the first resistor to the second resistor; and
a correction circuit connected between a ground and the connection point of the first resistor to the second resistor so that the correction circuit is parallel to the third resistor and the first capacitor.

10. The optical receiver circuit according to claim 9, wherein the correction circuit includes a resistor and a capacitor.

11. The optical receiver circuit according to claim 9, further comprising a comparator having a first input terminal connected to the output terminal of the inverting amplifier, and a second input terminal connected to a reference power source.

12. An optical receiver circuit comprising:
a light receiving element configured to output a current according to input light;
an inverting amplifier having an input terminal and an output terminal, the input terminal connected to the light receiving element;
a first resistor and a second resistor that are connected in series between the input terminal of the inverting amplifier and the output terminal of the inverting amplifier;
a third resistor, a fourth resistor, and a first capacitor that are connected in series to one another between a ground and a connection point of the first resistor to the second resistor; and
a second capacitor connected between a ground and a connection point of the third resistor to the fourth resistor.

13. An optical receiver circuit comprising:
a light receiving element configured to output a current according to input light;
an inverting amplifier having an input terminal and an output terminal, the input terminal connected to the light receiving element;
a first resistor and a second resistor that are connected in series between the input terminal of the inverting amplifier and the output terminal of the inverting amplifier;
a first capacitor, a second capacitor, and a third resistor that are connected in series to one another between a ground to a connection point of the first resistor to the second resistor;
a fourth resistor connected between a ground and a connection point of the first capacitor to the second capacitor.

14. An optical receiver circuit comprising:
a light receiving element configured to output a current according to input light;
an inverting amplifier having an input terminal and an output terminal, the input terminal connected to the light receiving element;
a first resistor and a second resistor that are connected in series between the input terminal of the inverting amplifier and the output terminal of the inverting amplifier;
a third resistor and a first capacitor that are connected in series between a ground and a connection point of the first resistor to the second resistor;
a fourth resistor and a fifth resistor that are connected between the input terminal of the inverting amplifier and the output terminal of the inverting amplifier so that the fourth resistor and the fifth resistor are parallel to the first resistor and the second resistor; and
a sixth resistor and a second capacitor that are connected in series between a ground and a connection point of the fourth resistor to the fifth resistor.
